(19) United States
(12) Patent Application Publication
(10) Pub. No.: US 2009/0304911 A1
(43) Pub. Date: Dec. 10, 2009

(54) METHOD OF FORMING CIRCUITS ON CIRCUIT BOARD

(75) Inventors: CHENG-HSIEN LIN, Tayuan (TW); QIU-YUE ZHANG, Shenzhen City (CN); YAO-WEN BAI, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: FUKUI PRECISION COMPONENT (SHENZHEN) CO., LTD., Shenzhen City (CN); FOXCONN ADVANCED TECHNOLOGY INC., Tayuan (TW)

(21) Appl. No.: 12/261,321

(22) Filed: Oct. 30, 2008

(30) Foreign Application Priority Data
Jun. 4, 2008 (CN) 200810301963.X

(51) Int. Cl. H05K 3/12; B05D 5/12

(52) U.S. Cl. 427/97.4; 427/97.6

(57) ABSTRACT

A method of forming a circuit on a circuit board includes the following steps. Firstly, a surface of an insulating substrate is hydrophilically treated. Secondly, a first circuit layer having a number of electrical traces is formed on the hydrophilically treated surface, the first circuit layer is comprised of a soluble palladium salt. Thirdly, the soluble palladium salt of the first circuit layer is reduced into metallic palladium, thereby obtaining a second circuit layer comprised of metallic palladium. Lastly, an electrically conductive layer is formed on the second circuit layer.

### CROSS-REFERENCE TO RELATED APPLICATION

This application is related to a commonly-assigned copending application: Ser. No. 12/235,994, entitled “METHOD OF FORMING CIRCUITS ON CIRCUIT BOARD”. Disclosures of the above-identified application are incorporated herein by reference in its entirety.

### BACKGROUND

1. Field of the Invention

The present invention relates to method of manufacturing printed circuit boards and, particularly, to a method of forming a circuit on a circuit board.

2. Description of Related Art

A popular method for forming circuits on a printed circuit board uses ink jet printing. Ink jet printing is a non-impact dot-matrix printing technology in which droplets of ink are fired from a small aperture directly to a specified position on a medium to create an image.

Generally, circuits of printed circuit boards are manufactured using a photo-lithographic process. The photo-lithographic process includes a series of processes, such as, coating photoresist layer on a copper clad laminate, exposing the photoresist layer to light beam, developing the photoresist layer to obtain a photoresist pattern, etching the copper clad laminate to obtain a circuit pattern corresponding to the photoresist pattern, peeling off the photoresist pattern, and other required steps. Clearly, the photo-lithographic process is complicated, needs a lot of chemical materials and creates a great deal of non-disposable waste. Therefore, the photo-lithographic process complicates the process of manufacturing the printed circuit boards and cause pollution to the environment.

What is needed, therefore, is a method of forming a circuit on a circuit board which can overcome the above-described problems.

### SUMMARY

An exemplary embodiment of a method of forming a circuit on a circuit board includes the following steps. Firstly, a surface of an insulating substrate is hydrophilically treated. Secondly, a first circuit layer having a number of electrical traces is formed on the hydrophilically treated surface, the first circuit layer is comprised of a soluble palladium salt. Thirdly, the soluble palladium salt of the first circuit layer is reduced into metallic palladium, thereby obtaining a second circuit layer comprised of the metallic palladium. Lastly, an electrically conductive layer is formed on the second circuit layer.

Advantages and novel features will become more apparent from the following detailed description when taken in conjunction with the accompanying drawings.

### BRIEF DESCRIPTION OF THE DRAWINGS

Many aspects of the present embodiment can be better understood with reference to the following drawings. The components in the drawings are not necessarily drawn to scale, the emphasis instead being placed upon clearly illustrating the principles of the present embodiment. Moreover, in the drawings, like reference numerals designate corresponding parts throughout the several views.

FIG. 1 is a flowchart of a method for manufacturing a printed circuit board, according to an exemplary embodiment.

FIG. 2 is a schematic cross-sectional view of an insulating substrate of forming a printed circuit board, according to the exemplary embodiment.

FIG. 3 is a schematic cross-sectional view of a first circuit layer formed on the insulating substrate of FIG. 2.

FIG. 4 is a schematic cross-sectional view of a second circuit layer converted from the first circuit layer of FIG. 3.

FIG. 5 is a schematic cross-sectional view of an electrically conductive metal layer formed on the second circuit pattern of FIG. 4.

### DETAILED DESCRIPTION

An embodiment will now be described in detail below and with reference to the drawings.

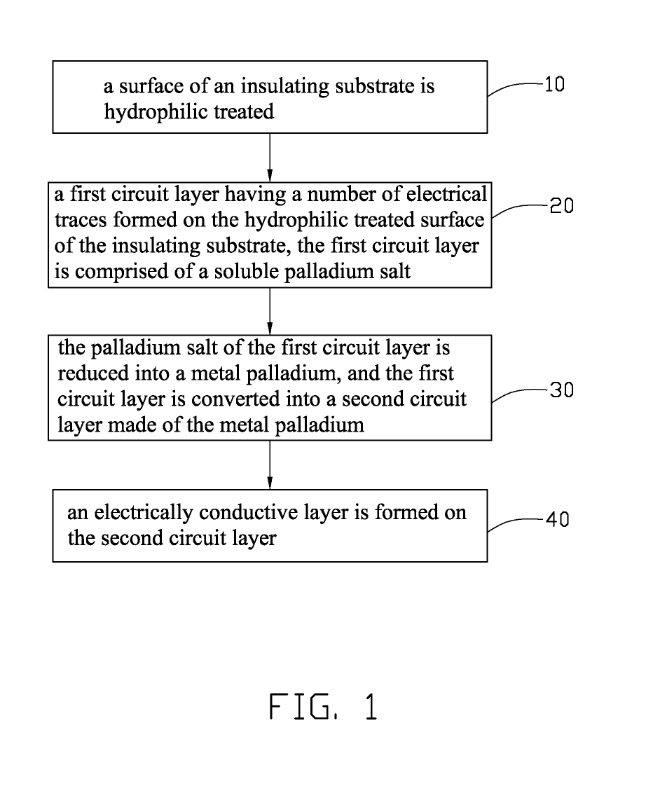

Referring to FIG. 1, an exemplary embodiment of a method of forming a circuit on a circuit board is shown. In step 10, a surface of an insulating substrate is hydrophilically treated. In step 20, a first circuit layer having a number of electrical traces formed on the hydrophilically treated surface of the insulating substrate. The first circuit layer is comprised of a soluble palladium salt. In step 30, the palladium salt of the first circuit layer is reduced into metallic palladium, and the first circuit layer is converted into a second circuit layer made of the metallic palladium. In step 40, an electrically conductive layer is formed on the second circuit layer.

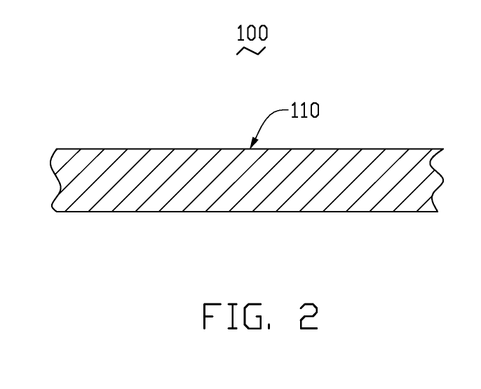

In step 10, referring to FIG. 2, a surface of an insulating substrate 100 is hydrophilically treated applying a surface modifying method. The insulating substrate 100 is made of a material suitable for making printed circuit boards, such as polyimide (PI), polyethylene terephthalate (PET), or polyarylene ether nitrile (PEN). In the present embodiment, the insulating substrate 100 is a polyimide layer and has a surface 110. In sequential process, a circuit layer is printed on the surface 110 using an ink jet printing method. In order to improve strength of adhesive bond between the surface 110 and the ink (i.e., the ink is used to form the circuit layer), the surface 110 is first hydrophilically treated. That is, the surface 110 is modified to form polar functional groups thereon. The polar functional groups have excellent hydrophilic property and capable of combining with the ink.

In the present embodiment, the insulating substrate 100 is a polyimide layer, and an alkaline solution is used to modify the surface 110. The detailed modifying process includes following steps. Firstly, the surface 110 is cleaned using a solvent such as acetone, alcohol, water, to remove pollutants, oil, grease or other contaminants from the surface 110. Secondly, the alkaline solution is used to treat the cleaned surface 110. The alkaline solution can be a potassium hydroxide or a mixture of a potassium hydroxide and a potassium permanganate. In the present embodiment, the insulating substrate 100 is immersed in a potassium hydroxide solution with a concentration of 5 mol/L, and the surface 110 is treated for about 5 minutes. Finally, the insulating substrate 100 is taken out of the potassium hydroxide solution, and cleaned to substantially remove the residual potassium hydroxide from the surface 110. For example, the surface 110 of the insulating substrate 100 is cleaned using a deionized water for appropriate times until the surface 110 is neutrality or near neutrality.

In the above-described modifying process, imide bonds in the polyimide of the surface 110 are broken in the potassium hydroxide solution and create carboxyl groups and amide groups. The carboxyl groups and amide groups are polar functional groups which have excellent hydrophilic property. In addition, the carboxyl groups are capable of bonding to positive ions. Therefore, in the present embodiment, potassium ions of the potassium hydroxide solution are bonded to the carboxyl groups. Therefore, the surface 110 of the insulating substrate 100 modified (i.e., hydrophilically treated) by the potassium hydroxide solution has a number of potassium ions bonded to the carboxyl groups.

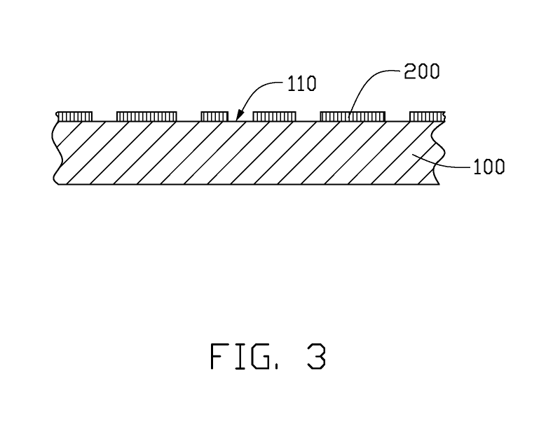

In step 20, referring to FIG. 3, a first circuit layer 200 is formed on the hydrophilically treated surface 110 of the insulating substrate 100, and the first circuit layer 200 is made of a soluble palladium salt. The first circuit layer 200 can be formed on the surface 110 using an ink jet printing method or a lithographic printing method. In the present embodiment, the first circuit layer 200 is formed on the surface 110 using the ink jet printing method. In an ink jet printing process, a nozzle of the ink jet printer is positioned close to the surface 110, and the ink is fired onto the surface 110 in a desired pattern, i.e., the first circuit layer 200. The ink includes a palladium salt solution, and a mol concentration of the palladium salt in the ink is in a range from about 10⁻⁴ mol/L to about 10⁻² mol/L. The palladium salt is selected from the group consisting of palladium sulfate, palladium chloride, palladium nitrate and palladium complex. In the present embodiment, the ink is a mixture solution of palladium chloride and ammonia chloride, and a weight ratio of the palladium chloride and ammonia chloride is about 1:1.

In order to improve strength of the adhesive bond between the first circuit layer 200 and the surface 110, a surfactant, viscosity modifier, binder material, moisturizing agent and other additives can be added to the ink to adjust viscosity, surface tension, and stability of the ink. The surfactant can be an anionic surfactant, cationic surfactant, or non-ionic surfactant. The binder material can be a polyurethane or a polyvinyl alcohol. In the present embodiment, the ink comprises the surfactant by volume in an amount of about 0.1 to 5 percent, the viscosity modifier by volume in an amount of about 0.1 to 50 percent, the binder material by volume in an amount of about 0.1 to 20 percent, the moisturizing agent by volume in an amount of about 0.1 to 50 percent, and other additives by volume in an amount of about 0.1 to 10 percent.

As described in step 10, the surface 110 modified (i.e., hydrophilically treated) by the potassium hydroxide solution has a number of potassium ions bonded to the carboxyl groups. In the present step 20, when the ink is formed on the surface 110, an ion exchange reaction occurs between the potassium ion in the surface 110 and the palladium ions in the ink. After the ion exchange reaction, the palladium ions substitute the potassium ions and bond to the carboxyl groups. That is, the ink is tightly bonded to the surface 110 and therefore, the first circuit layer 200 tightly binds to the surface 110.

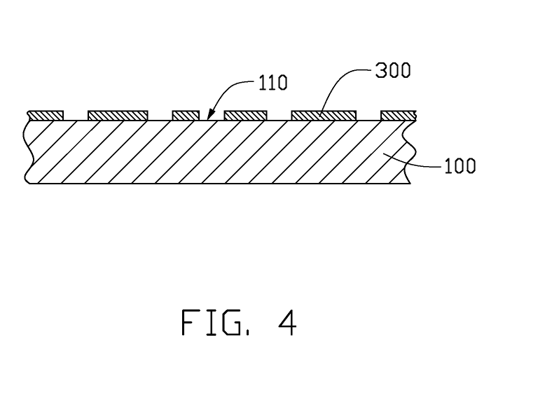

In step 30, referring to FIG. 4, the palladium ions of the first circuit layer 200 are reduced into metallic palladium using a non-ionic reducing agent, and therefore the first circuit layer 200 is, partially or preferably completely, converted into a second circuit layer 300 made of the metallic palladium. The non-ionic reducing agent is capable of preventing the palladium ions from desorbing from the carboxyl groups or the surface 110. The non-ionic reducing agent can be a gas or liquid reducing agent. The gas reducing agent can be ethylene, carbon monoxide, or hydrogen. The liquid reducing agent includes a strong reducing agent such as formaldehyde and hydrazine hydrate solution, and weak reducing agent such as acetone and glycol.

If the strong reducing agent is applied to reduce the palladium ions into the metallic palladium, take the formaldehyde solution for example, at a temperature of about 50 degrees Celsius, the insulating substrate 100 having the first circuit layer 200 formed thereon is immersed into the formaldehyde solution for a suitable period of time until the palladium ions of the first circuit layer 200 is reduced into metallic palladium. In the present example, the insulating substrate 100 is immersed into the formaldehyde solution for fifteen minutes. Then the insulating substrate 100 is taken out of the formaldehyde solution and cleaned using the deionized water. Thus, the first circuit layer 200 is converted into the second circuit layer 300.

Alternatively, if the weakly reducing agent is applied to reduce the palladium ions into the metallic palladium, take the acetone for example, the insulating substrate 100 having the first circuit layer 200 formed thereon is immersed into the acetone and irradiated by an ultraviolet radiation for a suitable period of time until the palladium ions of the first circuit layer 200 is reduced into metallic palladium. In the present example, the insulating substrate 100 is irradiated by an ultraviolet radiation for six minutes. Then the insulating substrate 100 is taken out of the acetone and cleaned using the deionized water. Thus, the first circuit layer 200 is converted into the second circuit layer 300.

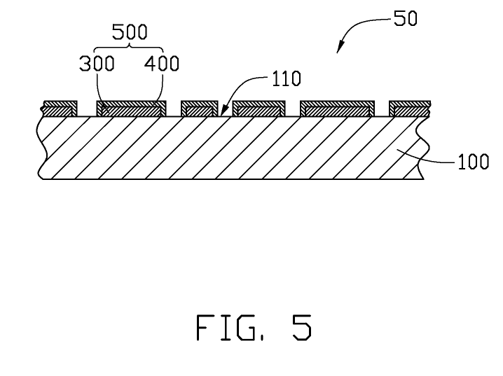

In step 40, an electrically conductive layer 400 is formed on the second circuit layer 300 to obtain a desired third circuit layer 500, thereby getting a circuit board 50, as shown in FIG. 5. That is, the second circuit layer 300 and the electrically conductive layer 400 compose the third circuit layer 500. The electrically conductive metal layer 400 can be formed on the second circuit layer 300 using an electro-plating method or an electroless-plating method. Because the second circuit layer 300 is transformed from the first circuit layer 200 made of the palladium salt, the second circuit layer 300 are composed of a number of discontinuous or spaced palladium particles and so may not properly conduct electricity. Therefore, the electrically conductive layer 400 is formed on the second circuit layer 300 to electrically conduct discontinuous or spaced palladium particles, thereby forming a properly electrically conductive third circuit layer 500. The electrically conductive layer 400 can be copper, nickel, or silver. In the present example, the electrically conductive layer 400 is made of copper.

Take the electroless-plating method for example, at a temperature of about 50 degrees Celsius, the insulating substrate 100 having the second circuit layer 300 formed thereon is immersed into an electroless-plating solution for a suitable period of time until the electrically conductive layer 400 is formed on and substantially electrically conduct the second circuit layer 300. The electroless-plating solution includes copper compound, reducing agent, and chelating agent. The copper compound can be copper sulfate or copper chloride. The reducing agent can be formaldehyde or acetaldehyde acid. The chelating agent can be disodium ethylenediamine tetraacetate (EDTA-2Na) or sodium tartrate. In the present embodiment, the electroless-plating solution includes copper sulfate 10 g/L, sodium tartrate 22 g/L, EDTA-2Na 50 g/L, formaldehyde 15 mL/L, and methanol 10 mL/L. In the present embodiment, the insulating substrate 100 is immersed into an electroless-plating solution for two minutes.

The obtained circuit board 50 includes the insulating substrate 100 having the hydrophilic treat or modified surface 110, and the third circuit layer 500 formed on the surface 110 of the insulating substrate 100. The hydrophilic treat or modified surface 110 has a number of polar functional groups bonded therein. The third circuit layer 500 includes the second circuit layer 300 made of palladium, and the electrically conductive layer 400 formed on the second circuit layer 300. The second circuit layer 300 strongly bonds to the hydrophilically treated or modified surface 110, and is enclosed or encapsulated in the electrically conductive layer 400.

The above-described method for manufacturing the printed circuit board has following advantageous. Firstly, the surface 110 of the insulating substrate 100 is modified (i.e., hydrophilically treated) using the potassium hydroxide solution and bonds a number of potassium ions thereto. In the sequential process of forming the first circuit layer 200, the strength of adhesive bond between the surface 110 and the first circuit layer 200 has been greatly improved. Secondly, the palladium ions of the first circuit layer 200 are reduced into metallic palladium using the non-ionic reducing agent, thereby preventing the palladium ions from desorbing from the carboxyl groups or the surface 110. Finally, the electrically conductive layer 400 formed on the second circuit layer 300 electrically conducts the discontinuous or spaced palladium particles in the second circuit layer 300, thereby the finally obtained third circuit layer 500 achieving an excellent electrically conductive characteristics.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A method of forming a circuit on a circuit board, the method comprising:
hydrophilically treating a surface of an insulating substrate;
forming a first circuit layer having a plurality of electrical traces on the hydrophilically treated surface, the first circuit layer comprised of a soluble palladium salt;
reducing the soluble palladium salt of the first circuit layer into metallic palladium, thereby obtaining a second circuit layer comprised of the metallic palladium; and
forming an electrically conductive layer on the second circuit layer.

2. The method as claimed in claim 1, wherein the surface of an insulating substrate is hydrophilically treated to form polar functional groups thereon.

3. The method as claimed in claim 2, wherein the surface of the insulating substrate is hydrophilically treated to form polar functional groups using a modifying process, the modifying process comprising providing a alkaline solution; immersing the insulating substrate in the alkaline solution for a time period; and cleansing the insulating substrate to substantially remove the alkaline solution from the surface of the insulating substrate.

4. The method as claimed in claim 3, wherein the alkaline solution is one of a potassium hydroxide and a mixture of a potassium hydroxide and a potassium permanganate.

5. The method as claimed in claim 4, wherein the insulating substrate is made of polyimide, and the surface of the insulating substrate is modified using the potassium hydroxide solution.

6. The method as claimed in claim 5, wherein the potassium hydroxide solution has a concentration of about 5 mol/L, and the insulating substrate is immersed in the potassium hydroxide solution for about 5 minutes.

7. The method as claimed in claim 6, wherein the surface of the insulating substrate is cleaned using a deionized water until the surface is substantially neutralized.

8. The method as claimed in claim 6, wherein after the insulating substrate is treated using the potassium hydroxide solution, imide bonds in the polyimide of the surface of the insulating substrate are converted into carboxyl groups and amide groups, and the potassium ions of the potassium hydroxide solution are bonded to the carboxyl groups.

9. The method as claimed in claim 8, wherein during the first circuit layer being formed on the hydrophilically treated surface, an ion exchange reaction occurs between the potassium ions bonded to the carboxyl groups on the surface of the insulating substrate and the palladium ions in the soluble palladium salt, whereby the palladium ions are bonded to the surface of the insulating substrate.

10. The method as claimed in claim 1, wherein the first circuit layer is formed on the hydrophilically treated surface using an ink jet printing method.

11. The method as claimed in claim 10, wherein the ink used to form the first circuit layer includes a soluble palladium salt, and a mol concentration of the palladium salt in the ink is in a range from about 10⁻⁴ mol/L to about 10⁻² mol/L.

12. The method as claimed in claim 11, wherein the soluble palladium salt is selected from the group consisting of palladium sulfate, palladium chloride, palladium nitrate and palladium complex.

13. The method as claimed in claim 11, wherein the ink is a mixture solution of palladium chloride and ammonia chloride, and a weight ratio of the palladium chloride and ammonia chloride is about 1:1

14. The method as claimed in claim 11, wherein the ink used to form the first circuit layer includes at least one of a surfactant, a viscosity modifier, a binder material and a moisturizing agent.

15. The method as claimed in claim 14, wherein the ink comprises the surfactant by volume in an amount of about 0.1 to 5 percent, the viscosity modifier by volume in an amount of about 0.1 to 50 percent, the binder material by volume in an amount of about 0.1 to 20 percent, the moisturizing agent by volume in an amount of about 0.1 to 50 percent, and other additives by volume in an amount of about 0.1 to 10 percent.

16. The method as claimed in claim 1, wherein the palladium salt is reduced into the metallic palladium using a non-ionic reducing agent.

17. The method as claimed in claim 16, wherein the non-ionic reducing agent is one of a gas reducing agent and a liquid reducing agent.

18. The method as claimed in claim 17, wherein the gas reducing agent is selected from the group consisting of ethylene, carbon monoxide and hydrogen.

19. The method as claimed in claim 17, wherein the liquid reducing agent is selected from the group consisting of formaldehyde, hydrazine hydrate, acetone and glycol.

20. The method as claimed in claim 1, wherein the electrically conductive metal is electro-plated on the second circuit layer using an electroless-plating solution, the electroless-plating solution comprises copper sulfate, sodium tartrate, EDTA-2Na, formaldehyde, and methanol.
